(19) United States
(12) Patent Application Publication
(10) Pub. No.: US 2013/0023120 A1
(43) Pub. Date: Jan. 24, 2013

(54) METHOD OF FORMING MASK PATTERN AND METHOD OF MANUFACTURING SEMICONDUCTOR DEVICE

(71) Applicants: Hidetami Yaegashi, Nirasaki-shi (JP); Yoshiki Igarashi, Nirasaki-shi (JP); Kazuki Narishige, Nirasaki-shi (JP); Takahito Mukawa, Nirasaki-shi (JP)

(72) Inventors: Hidetami Yaegashi, Nirasaki-shi (JP); Yoshiki Igarashi, Nirasaki-shi (JP); Kazuki Narishige, Nirasaki-shi (JP); Takahito Mukawa, Nirasaki-shi (JP)

(73) Assignee: Tokyo Electron Limited, Tokyo (JP)

(21) Appl. No.: 13/638,662

(22) PCT Filed: Mar. 28, 2011
(86) PCT No.: PCT/JP2011/057618

§ 371 Date: Oct. 1, 2012

(30) Foreign Application Priority Data
Apr. 2, 2010 (JP) 2010-085956

(51) Int. Cl. H01L 21/306

(52) U.S. Cl. 438/689; 257/E21.219

(57) ABSTRACT

A method of forming a mask pattern includes a first pattern forming step of etching an anti-reflection coating film by using as a mask a first line portion made up of a photo resist film formed on the anti-reflection film to form a pattern including a second line portion made up of the photo resist film and the anti-reflection film; an irradiation step of irradiating the photo resist film with electrons; a silicon oxide film forming step to cover the second line portion isotropically; and an etch back step of etching back the silicon oxide film such that the silicon oxide film is removed from the top of the second line portion as sidewalls of the second line portion. The method further includes a second pattern forming step of ashing the second line portion to form a mask pattern including a third line portion made up of the silicon oxide film and remains.

### FIELD OF THE INVENTION

The present invention relates to a method of forming a mask pattern and a method of manufacturing a semiconductor device.

### BACKGROUND OF THE INVENTION

With high integration of semiconductor devices, dimensions of wirings and isolation regions have a tendency of miniaturization. Such a miniaturized pattern is formed by providing a pattern in which line portions formed of a photo resist film (hereinafter abbreviated as a “resist film”) are arranged at predetermined intervals by using a photolithography technique, and etching a film to be etched using the formed pattern as a mask pattern. The recent miniaturization of semiconductor devices gets up to requirement of dimension of less than resolution limit of the photolithography technique.

A so-called “double patterning” method is a method of forming a fine mask pattern having a dimension of less than resolution limit of the photolithography technique. The double patterning method includes two steps: a first pattern forming step and a second pattern forming step carried out after the first pattern forming step. The double patterning method forms a mask pattern having finer line width and space width than a mask pattern formed by a single patterning.

As another double patterning method, there has been also proposed a sidewall patterning (SWP) method of forming mask a pattern having smaller arrangement intervals than a pattern including an original line portion serving as a core member by using sidewalls, which are formed in both sides of the line portion as a mask. In this method, a resist pattern having the line portion formed thereon is first formed by forming a resist film, and then a silicon oxide film or the like is formed to cover a surface of the line portion isotropically. Then, the silicon oxide film is etched back to leave only sidewall portions thereof covering the sides of the line portion, and thereafter, the line portion is removed to obtain the left sidewall of the silicon oxide film as a mask pattern (see, e.g., Japanese Patent Application Publication No. 2009-99938. In this manner, a fine mask pattern having a dimension of less than resolution limit of the photolithography technique is formed.

However, the above-described SWP method of forming the fine mask pattern having a resolution lower than a resolution limit of the photolithography technique has the following problem.

In this SWP method, when the silicon oxide film is formed or the formed silicon oxide film is etched back, the line portion formed of the resist film serving as the core member is likely to be exposed to plasma. Since the resist film exposed to plasma reacts with the plasma, a surface of the line portion may be roughened or deformed, which may result in deterioration of flatness of a sidewalls of the line portion or reduction of a line width of the line portion.

If the flatness of the sidewalls of the line portion is deteriorated, the silicon oxide film covering the sides of the line portion cannot be formed with high flatness. Thus, the mask pattern made up of the remaining sidewall portions cannot have a uniform and highly precise shape. In addition, if the line width of the line portion is reduced, the sidewall portions covering the sides of the line portion are likely to be inclined or collapsed in one direction. In either case, since the sidewall portions cannot have a uniform and highly precise shape, when an underlying layer is etched using the mask pattern including the sidewall portions as a mask, a shape formed by the etching cannot have uniformity and high precision.

### SUMMARY OF THE INVENTION

In view of the above, the invention provides a mask pattern forming method and a semiconductor device manufacturing method, which are capable of preventing a core member made up of a resist film from being deformed when a silicon oxide film for forming sidewall portions is formed and the silicon oxide film thus formed is etched back in case of forming a fine mask pattern using a SWP method.

In accordance with one aspect of the present invention, there is provided A method of forming a mask pattern, including: a first pattern forming step of etching an anti-reflection coating film by using as a mask a first line portion made up of a photo resist film formed on the anti-reflection film to form a pattern including a second line portion made up of the photo resist film and the anti-reflection film; an irradiation step of irradiating the photo resist film with electrons; a silicon oxide film forming step of forming a silicon oxide film to cover the second line portion isotropically; an etch back step of etching back the silicon oxide film such that the silicon oxide film is removed from the top of the second line portion as sidewalls of the second line portion; and a second pattern forming step of ashing the second line portion to form a mask pattern including a third line portion which is made up of the silicon oxide film and remains as the sidewalls.

In accordance with the invention, it is possible to prevent a core member made up of a resist film from being deformed when a silicon oxide film for forming the sidewall portions is formed and the silicon oxide film thus formed is etched back in forming a fine mask pattern using a SWP method.

### BRIEF DESCRIPTION OF THE DRAWINGS

FIG. 1 is a schematic sectional view showing a plasma processing apparatus in accordance with a first embodiment.

FIG. 2 is a view showing an example of a controller for controlling various components and the overall sequence of the plasma processing apparatus.

FIG. 3 is a flow chart used to explain a mask pattern forming method and a semiconductor device manufacturing method in accordance with the first embodiment.

FIGS. 4A to 4C are schematic views used to explain a mask pattern forming method and a semiconductor device manufacturing method in accordance with the first embodiment, showing states of a wafer in various steps.

FIGS. 4D to 4F are schematic views used to explain a mask pattern forming method and a semiconductor device manufacturing method in accordance with the first embodiment, showing states of a wafer in various steps, subsequent to FIG. 4A.

FIGS. 4G to 4I are schematic views used to explain a mask pattern forming method and a semiconductor device manufacturing method in accordance with the first embodiment, showing states of a wafer in various steps, subsequent to FIG. 4F.

FIG. 5 is a schematic view used to explain the principle of a modifying process performed by irradiating a line portion with electrons in accordance with the first embodiment.

FIG. 6 is a graph showing a theoretical relationship between electron energy and electron penetration depth when a resist is irradiated with electrons.

FIGS. 7A to 7C are schematic sectional views showing a wafer after an etch back step is performed in a conventional mask pattern forming method and a conventional semiconductor device manufacturing method.

FIG. 8 is a flow chart used to explain various steps in another example of the mask pattern forming method and the semiconductor device manufacturing method in accordance with the first embodiment.

FIG. 9 is a schematic sectional view showing a state of a wafer provided with a dense portion A1 and a sparse portion A2.

FIG. 10 is a schematic sectional view showing a plasma processing apparatus in accordance with a second embodiment.

### DETAILED DESCRIPTION OF THE EMBODIMENTS

Embodiments of the present invention will now be described with reference to the drawings which form a part hereof.

### First Embodiment

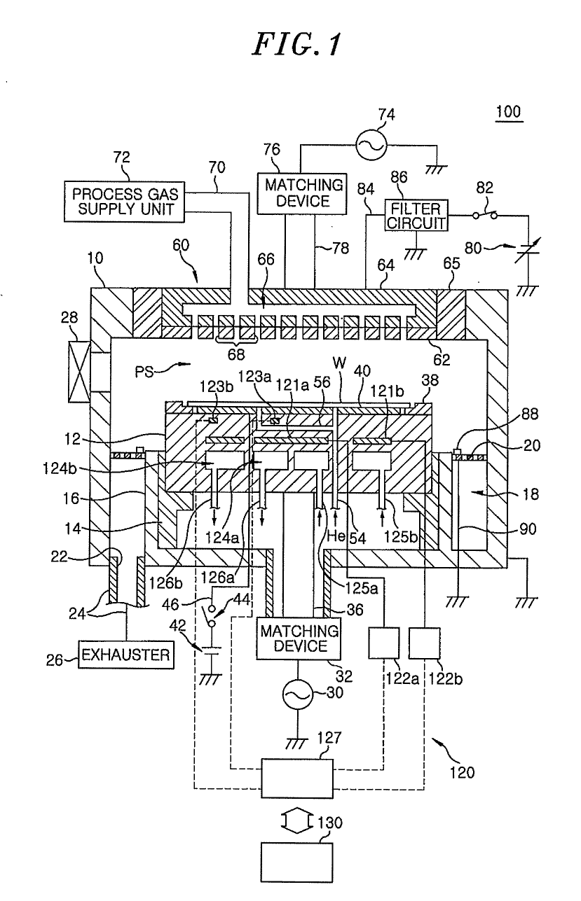

A method of forming a mask and a method of manufacturing a semiconductor device in accordance with a first embodiment of the present invention will be described below with reference to FIGS. 1 to 9.

First, a plasma processing apparatus in accordance with this embodiment which is adapted for practice of the method of forming a mask and the method of manufacturing a semiconductor device in accordance with the first embodiment of the present invention will be described.

Referring to FIG. 1, a plasma processing apparatus 100 is implemented with a capacitive coupling type plasma etching apparatus and has a cylindrical chamber (process chamber) 10 made of metal such as aluminum, stainless steel or the like. The chamber is grounded.

Within the chamber is horizontally placed a disc-like susceptor 12 serving as a lower electrode, on which a semiconductor wafer W (hereinafter abbreviated as a “wafer W”) is mounted as a substrate to be processed, for example. The susceptor 12 is made of, for example, aluminum and is supported by a tube-like insulating support 14 extending vertically upward from the bottom of the chamber 10. An annular exhaust path 18 is interposed between a sidewall of the chamber 10 and a tube-like conductive support (inner wall portion) 16 extending vertically upward from the bottom of the chamber 10 along the periphery of the tube-like insulating support 14. A ring-like exhaust ring (baffle plate) 20 is attached to an entrance of the exhaust path 18 and an exhaust port 22 is provided on the bottom of the exhaust path 18. An exhauster 26 is connected to the exhaust port 22 via an exhaust pipe 24. The exhauster 26 has a vacuum pump such as a turbo molecular pump or the like and can exhaust a process space of the chamber 10 up to a desired degree of vacuum. A gate valve 28 to open/close a carry-in/out port of the wafer W is attached to the sidewall of the chamber 10.

A high frequency power supply 30 is electrically connected to the susceptor 12 via a matching device 32 and a lower power feed bar 36. The high frequency power supply 30 outputs high frequency power. The high frequency power has a frequency (typically equal to or less than 13.56 MHz) which has contribution to introduction of ions toward the wafer W on the susceptor 12. The matching device 2 matches impedance between the high frequency power supply 30 and a load (mainly an electrode, plasma, chamber or the like) and can automatically correct matching impedance.

The wafer W to be processed is mounted on the susceptor 12. The susceptor 12 has a diameter larger than that of the wafer W. A focus ring (correction ring) 38 surrounding the wafer W mounted on the susceptor 12 is provided on the susceptor 12.

An electrostatic chuck 40 for wafer absorption is provided on the top of the susceptor 12. The electrostatic chuck 40 is formed of a film or plate-like dielectric in which a sheet or mesh-like conductor is contained. The conductor is electrically connected to a DC power supply 42, which is placed outside the chamber 10, via a switch 44 and a power feed line 46. The wafer W can be absorbed and held on the electrostatic chuck 40 by virtue of a Coulomb force produced by a DC voltage applied from the DC power supply 42.

A temperature distribution controller 120 is provided in the susceptor 12. The temperature distribution controller 120 includes heaters 121a and 121b, heater power supplies 122a and 122b, thermometers 123a and 123b and refrigerant passages 124a and 124b.

The central heater 121a is provided at the central portion in the susceptor 12 and the circumferential heater 121b is provided outside the central heater 121a. The central heater power supply 122a is connected to the central heater 121a and the circumferential heater power supply 122b is connected to the circumferential heater 121b. The central heater power supply 122a and the circumferential heater power supply 122b can provide the susceptor 12 with a desired temperature distribution along a radial direction by independently adjusting power supplied to the central heater 121a and the circumferential heater 121b, respectively. Accordingly, a desired temperature distribution along the radial direction can be generated in the wafer W.

The central thermometer 123a and the circumferential thermometer 123b are provided within the susceptor 12. The central thermometer 123a and the circumferential thermometer 123b can measure temperature of the central and circumferential regions of the susceptor 12 and accordingly derive temperature of the central and circumferential regions of the wafer W therefrom. Signals indicating the temperature measured by the central thermometer 123a and the circumferential thermometer 123b are sent to a temperature controller 127. The temperature controller 127 adjusts outputs of the central heater power supply 122a and the circumferential heater power supply 122b such that temperature of the wafer W derived from the measured temperature reaches a target temperature. The temperature controller 127 is connected to a controller 130 which will be described later.

The central refrigerant passage 124a is provided at the central region within the susceptor 12 and the circumferential refrigerant passage 124b is provided outside the central refrigerant passage 124a. Refrigerants having different temperatures are circulated from a chiller unit (not shown). More specifically, a refrigerant is introduced from a central introduction pipe 125a into the central refrigerant passage 124a, is circulated through the central refrigerant passage 124a, and is discharged from the central refrigerant passage 124a through a central discharging pipe 126a. Another refrigerant is introduced from a circumferential introduction pipe 125b into the circumferential refrigerant passage 124b, is circulated through the circumferential refrigerant passage 124b, and is discharged from the circumferential refrigerant passage 124b through a circumferential discharging pipe 126b. Examples of the refrigerants used may include cooling water, fluorocarbon-based liquid and so on.

The temperature of the susceptor 12 is adjusted by heating by the central heater 121a and the circumferential heater 121b and cooling by the refrigerants. Accordingly, the wafer W is adjusted to a predetermined temperature by exchange of heat with the susceptor 12, including heat by radiation from plasma and irradiation of ions included in plasma. In this embodiment, the susceptor 12 has the central heater 121a and the central refrigerant passage 124a in its central region and the circumferential heater 121b and the circumferential refrigerant passage 124b outside these central heater 121a and central refrigerant passage 124a. Accordingly, the temperature of the wafer W can be independently adjusted at the central region and the circumferential region and the temperature distribution in the plane of the wafer W can be adjusted.

In this embodiment, in order to provide a more precise temperature distribution of the wafer W, heat transfer gas (e.g., He gas) from a heat transfer gas supply unit (not shown) is supplied between the electrostatic chuck 40 and the wafer W via a gas supply pipe 54 and a gas passage 56 in the susceptor 12.

An upper electrode 60 which faces the subsceptor 12 in parallel and serves as a shower head is provided in the ceiling of the chamber 10. The upper electrode (shower head) 60 includes an electrode plate 62 facing the susceptor 12, and an electrode support 64 detachably supporting the electrode plate 62 from its rear (top). In addition, a gas diffusion chamber 66 is provided within the electrode support 64. A plurality of gas discharging holes 68 communicating the gas diffusion chamber 66 to the inner space of the chamber 10 are formed in the electrode support 64 and the electrode plate 62. A space defined between the electrode plate 62 and the susceptor 12 corresponds to a plasma generation space or a process space PS. The gas diffusion chamber 66 is connected to a process gas supply unit 72 via a gas supply pipe 70.

Since the electrode plate 62 of the upper electrode 60 is exposed to plasma for processing, it is preferably made of a material which has no adverse effect on a process even if it is sputtered by ion impact from the plasma. In this embodiment, since the electrode plate 62 (particularly, its surface) acts as a DC application member, it is preferable that the electrode plate 62 has good conductivity for DC current. Examples of such a material may include Si-contained conductive material such as Si, SiC or the like, carbon (C) and so on. The electrode support 64 may be made of alumite-treated aluminium or the like. The upper electrode 60 is attached to the chamber 10 via a ring-like insulator 65 placed between the upper electrode 60 and the chamber 10. The upper electrode 60 is electrically floated from the chamber 10 by the insulator 65.

A high frequency power supply 74 is electrically connected to the upper electrode 60 via a matching device 76 and an upper power feed bar 78. The high frequency power supply 74 outputs high frequency power having a frequency (typically equal to or more than 40 MHz) which has contribution to generation of plasma. The matching device 76 matches impedance between the high frequency power supply 74 and a load (mainly, an electrode, plasma, chamber) and can automatically adjust the matching impedance.

An output terminal of a variable DC power supply 80 outside the chamber 10 is electrically connected to the upper electrode 60 via a switch 82 and a DC power feed line 84. The variable DC power supply 80 can output a DC voltage V_{DC} of, for example, −2000 to +1000 V.

A filter circuit 86 provided in the way of the DC power feed line 84 allows the DC voltage V_{DC} to be applied from the filter circuit 86 to the upper electrode 60. On the other hand, the filter circuit 86 can transmit a high frequency power to a ground line. Accordingly, there is little possibility of flow of the high frequency power from the susceptor 12 into the variable DC power supply 80 via the process space PS, the upper electrode 60 and the DC power feed line 84.

In addition, a ring-like DC ground part (DC ground electrode) 88 made of a conductive material such as Si, SiC or the like is attached to the top surface of the baffle plate 20 within the chamber 10. The DC ground part 88 is fixedly grounded via a ground line 90. The DC ground part 88 is not limited to the top surface of the baffle plate 20 but may be provided at a position facing the process space PS. For example, the DC ground part 88 may be provided near the apex of the tube-like support 16 or radially outwardly of the upper electrode 60.

Operation of various parts within the plasma processing apparatus 10, for example, the exhauster 26, the high frequency power supplies 30 and 74, the switches 44, 82, the process gas supply unit 72, the variable DC power supply 80, the chiller unit (not shown), the heat transfer gas supply unit (not shown) and so on, and the overall operation (sequence) of the apparatus are controlled by the controller 130, for example, a microcomputer.

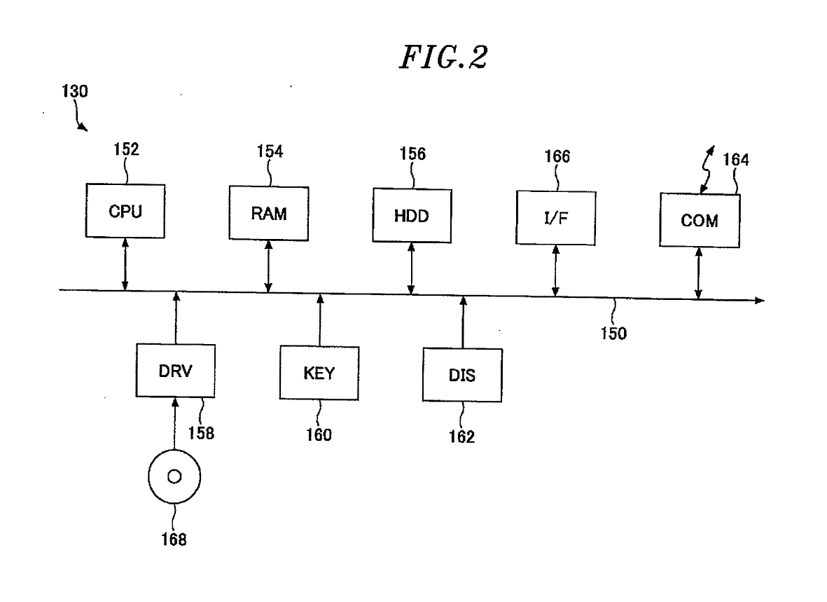

As shown in FIG. 2, the controller 130 includes a processor (or CPU) 152, a memory 154 such as RAM, a program storage device 156 such as HDD, a disk drive (DRV) 158 such as a flexible disk or an optical disk, an input device (KEY) 160 such as a keyboard, a mouse or the like, a display (DIS) 162, a network/interface (COM) 164, and a peripheral interface (I/F) 166 which are connected via a bus 150 to each other.

The processor (CPU) 152 reads required program codes from a storage medium 168 such as a flexible disk or an optical disk loaded in the disk drive (DRV) 18 and stores the read codes in HDD 156. The required program codes may be downloaded from a network via the network/interface 164. The processor (CPU) 152 loads the program codes, which are required for a process to be executed, from the program storage device (HDD) 156 into the working memory (RAM) 154 and executes steps for required computing process. The processor (CPU) 152 controls various parts in the apparatus, particularly the exhauster 26, the high frequency power supplies 30 and 74, the process gas supply unit 72, the variable DC power supply 80, the switch 82, the temperature distribution controller 120 and so on through the peripheral interface (I/F) 166.

In the plasma processing apparatus 100, in order to etch the wafer W on the susceptor 12, a predetermined flow rate of process gas including etchant gas is introduced from the process gas supply unit 72 into the chamber 10 and the internal pressure of the chamber 10 is adjusted to a preset value by the exhauster 26. In addition, a first high frequency (equal to or more than 40 MHz) power for plasma generation is applied from the high frequency power supply 74 to the upper electrode 60 via the matching device 76 and the upper power feed bar 78, and at the same time, a second high frequency (equal to 13.56 MHz) power for ion introduction is applied from the high frequency power supply 30 to the susceptor 12 via the matching device 32 and the lower power feed bar 36. In addition, with the switch 44 switched on, the wafer W is attracted to the electrostatic chuck 40 by an electrostatic absorptive force. Accordingly, heat transfer gas (He gas) is confined in a contact interface between the wafer W and the electrostatic chuck 40. The process gas discharged from the gas discharging holes 68 of the upper electrode 60 is plasmalized in the process space PS by the high frequency power applied between both electrodes 12 and 60, and a film to be processed on the wafer W is etched into a desired pattern by radicals and ions generated by the plasma.

In this plasma etching, the first high frequency power having a relatively high frequency (equal to or more than 40 MHz, preferably 60 MHz) suitable for plasma generation is applied from the high frequency power supply 74. Accordingly, the plasma can be kept at a preferred ionized state and can be made highly dense. As a result, highly dense plasma can be generated even under a lower pressure condition. At the same time, the second high frequency power having a relatively low frequency (equal to or less than 13.56 MHz) suitable for ion introduction is applied. Accordingly, anisotropic etching with high selectivity for the film on the wafer W can be carried out. In addition, the first high frequency power for plasma generation is necessary for any plasma process but the second high frequency power for ion introduction may or not be used depending on the process.

In carrying out the plasma etching, a DC voltage (typically −900 V to 0 V) is applied from the variable DC power supply 80 to the upper electrode 60. This allows for improvement of plasma ignition stability, resist selectivity, etching speed, etching uniformity and so on.

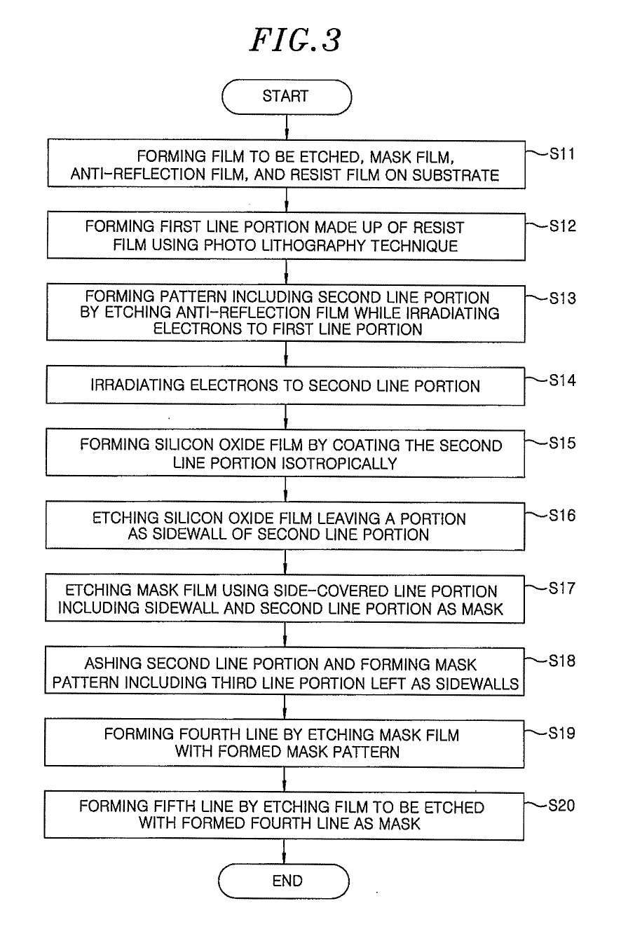

Next, a method of forming a mask pattern and a method of manufacturing a semiconductor device in accordance with this embodiment will be described with reference to FIGS. 3 to 6.

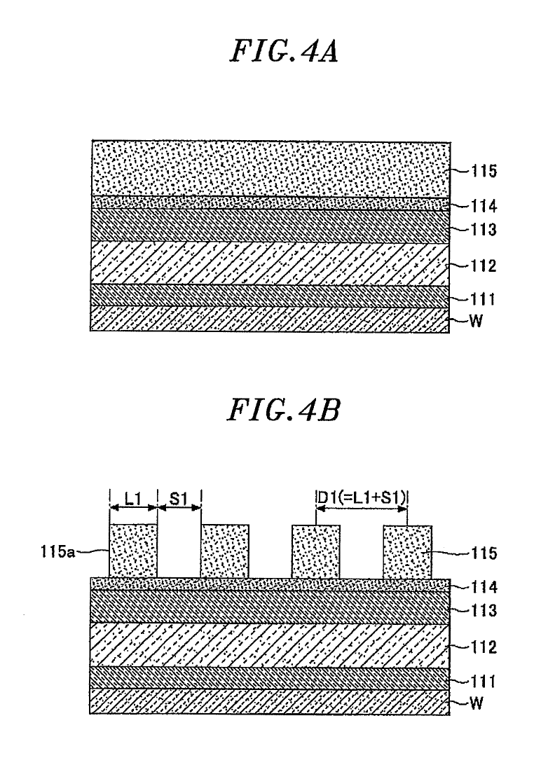

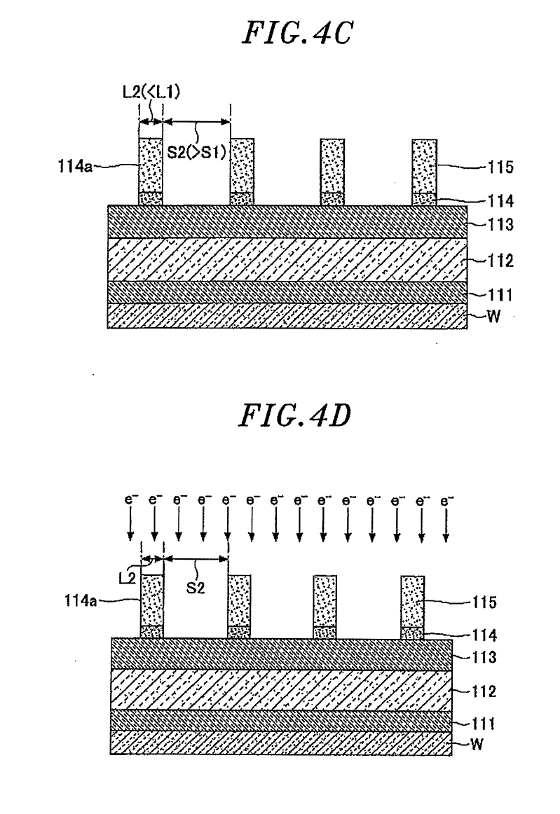

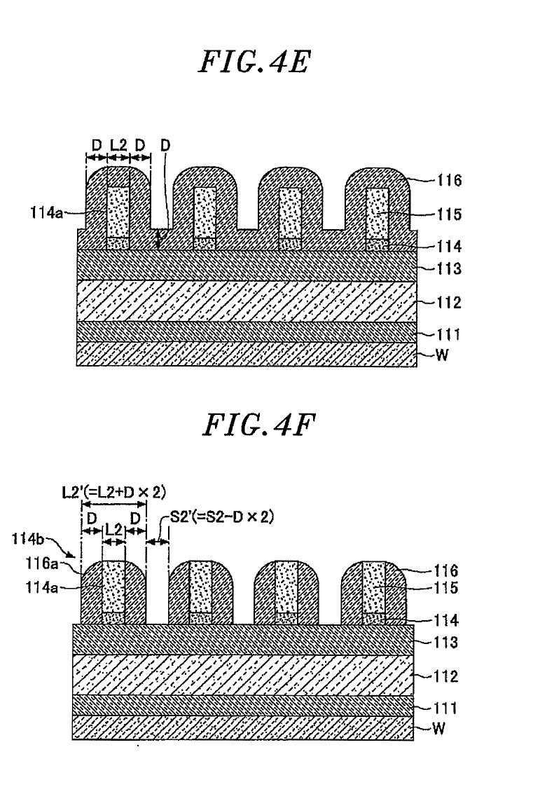

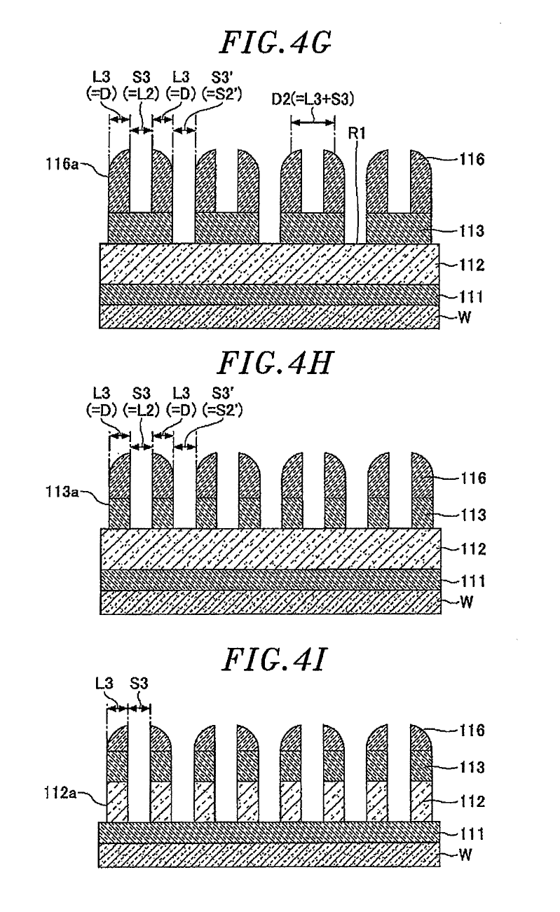

First, a stacking step S11 is performed. In the stacking step S11, an insulating film 111, a film 112 to be etched, a mask film 113, an anti-reflection film 114 and a resist film 115 are stacked on the wafer W, for example, a silicon substrate, as shown in FIG. 4A.

The film 112 to be etched is a film to be finally etched in a semiconductor device manufacturing method including a mask pattern forming method in accordance with this embodiment. The insulating film 111 may be formed of a silicon oxide (SiO₂) film which acts as, for example, a gate insulating film and is made of, for example, tetraethoxysilane (TEOS). Further, the film 112 to be etched may be formed of a polysilicon film acting as, for example, a gate electrode after etching process. Thickness of the film 112 to be etched may be, for example, 90 nm.

The mask film 113 acts as a hard mask when the film 112 to be etched, which lies below the mask film 113, is etched. A pattern of third line portion 116a formed of a silicon oxide film 116 to be formed in a silicon oxide film forming step S15 (which will be described later) is transferred onto the mask film 113. It is preferable that the mask film 113 has high selectivity to the film 112 to be etched when the film 112 to be etched is subjected to etching process. That is, it is preferable to provide a high ratio of an etching rate of the film 112 to be etched to an etching rate of the mask film 113. An example of the mask film 113 may include an inorganic film such as a SiN film, a SiON film or the like. Thickness of the mask film 113 may be, for example, 26 nm.

The anti-reflection film 114 acts as BARC (Bottom Anti-Reflective Coating) when the resist film 115 formed thereon is exposed. An example of the anti-reflection film 114 may include a CₓH_{y}O_{z} film called “organic BARC.” Thickness of the anti-reflection film 114 may be, for example, 30 nm.

The resist film 115 is formed on the wafer W via the anti-reflection film 114. Further, the resist film 115 is exposed and developed to provide a first line portion 115a which serves as a core member in the subsequent SWP. Thickness of the resist film 115 may be, for example, 100 nm.

Next, a photolithography step S12 is performed. In the photolithography step S12, a photolithographic technique is used to form the first line portion 115a made up of the resist film 115, as shown in FIG. 4B.

More specifically, a pattern including the first line portion 115a made up of the resist film 115 is formed by exposing and developing the resist film 115 formed on the anti-reflection film 114 through a photo mask (not shown) having a predetermined pattern. The first line portion 115a acts as a mask when the anti-reflection film 114 is etched. The first line portion 115a has a line width L1 and a space width S1 and is arranged at an interval D1 (=L1+S1). The line width L1 and the space width S1 are, for example, 60 nm without being particularly limited.

The line portion is a structure extending along a first direction on a plane and is arranged at a predetermined distance from an adjacent structure of the same kind along a second direction perpendicular to the first direction. The line width corresponds to a length along the second direction of the line portion. The space width corresponds to a length of a gap between two adjacent line portions along the second direction. An arrangement interval between line portions corresponds to a distance between the center of one line portion and the center of an adjacent line portion.

Next, mask pattern forming steps S13 to S18 are performed. First, in a first pattern forming step S13, the wafer W is irradiated with plasma and the anti-reflection film 114 is etched using the first line portion 115a made up of the resist film 115 formed on the wafer W via the anti-reflection film 114, as a mask. Accordingly, a pattern including a second line portion 114a made up of the resist film 115 and the anti-reflection film 114 is formed.

In addition, in the first pattern forming step S13, the second line portion 114a having a line width L2 smaller than the line width L1 of the first line portion 115a may be formed by etching the anti-reflection film 114 and trimming the first line portion 115a. In this embodiment, a case where the trimming of the first line portion 115a is simultaneously performed will be hereinafter described in detail.

In the first pattern forming step S13, an appropriate flow rate of process gas is introduced from the process gas supply unit 72 of the plasma processing apparatus 100 into the chamber 10 and the internal pressure of the chamber 10 is adjusted to a preset value by the exhauster 26. The first high frequency (equal to or more than 40 MHz) for plasma generation is applied from the high frequency power supply 74 to the upper electrode 60 via the matching device 76 and the upper power feed bar 78. In addition, with the switch 44 switched on, the wafer W is attracted by the electrostatic chuck 40 by virtue of an electrostatic absorptive force. Accordingly, the heat transfer gas (He gas) is confined in the contact interface of the wafer W and the electrostatic chuck 40. Process gas discharged from the gas discharging holes 68 of the upper electrode 60 is made into plasma in the process space PS by the high frequency power applied between both electrodes 12 and 60.

In the first pattern forming step S13, examples of the process gas may include mixtures of CF-based gas such as CF₄, C₄F₈, CHF₃, CH₃F, CH₂F₂ and the like, and Ar gas and so on, or gas obtained by adding oxygen to the mixtures as necessary.

Using the above-mentioned process gas, the anti-reflection film 114 is etched using the first line portion 115a made up of the resist film 115 as a mask, while the first line portion 115a is being trimmed. As a result, the second line portion 114a made up of the resist film 115 and the anti-reflection film 114 and having the line width L2 (FIG. 4C) smaller than the line width L1 (FIG. 4B) of the first line portion 115a is formed. That is, a magnitude relationship between the line width L1 and space width S1 of the first line portion 115a and the line width L2 and space width S2 of the second line portion 114a is as follows: L2<L1 and S2>S1. Values of L2 and S2 are not particularly limited. For example, L2 and S2 may be 30 nm and 90 nm, respectively.

Here, when a negative high DC voltage V_{DC} is applied from the variable DC power supply 80 to the upper electrode 60, an upper ion sheath SH_{U} formed between the upper electrode 60 and plasma PR becomes thick and a sheath voltage V_{U} becomes substantially equal to the DC voltage. Accordingly, ions (+) in the plasma PR are accelerated under an electric field of the upper ion sheath SH_{U} such that they have high kinetic energy. When the ions impact on the upper electrode 60 (the electrode plate 62) with high impact energy, a large quantity of secondary electrons (e⁻) are emitted from the electrode plate 62. The secondary electrons (e⁻) emitted from the electrode plate 62 are accelerated in the reverse direction to the ions under the electric field of the upper ion sheath SH_{U}, escape from the plasma PR, traverse a lower ion sheath SH_{L}, and are injected into the surface of the wafer W on the susceptor 12 with high energy. That is, the first line portion 115a made up of the resist film 115 on the surface of the wafer W is irradiated with the electrons. The irradiation of the electrons allows high molecules of the resist constituting the first line portion 115a to absorb energy of the electrons, thereby causing change in its composition and structure, cross-linking reaction, etc. Accordingly, the first line portion 115a is modified.

At this time, although the secondary electrons (e⁻) pass through the plasma PR at a uniform velocity, a lower sheath voltage V_{L} (or a self-bias voltage) of the lower ion sheath SH_{L} is better, preferably typically equal to or more than 100 V. Accordingly, power of the second high frequency (13.56 MHz) signal applied to the susceptor 12 may be set to equal to or more than 50 W, preferably 0 W.

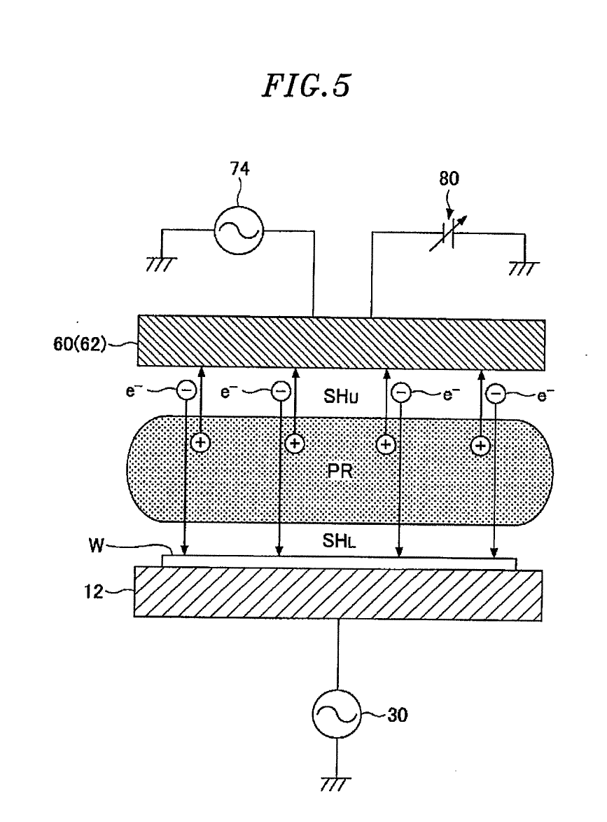

As can be seen from the principle shown in FIG. 5, the energy of the electrons injected into the first line portion 115a made up of the resist film 115 on the wafer W can be increased with increase in the absolute value of the negative DC voltage V_{DC} applied to the upper electrode 60. As a result, a penetration depth, i.e., a modification depth of the electrons into the first line portion 115a made up of the resist film 115 on the wafer W can be increased.

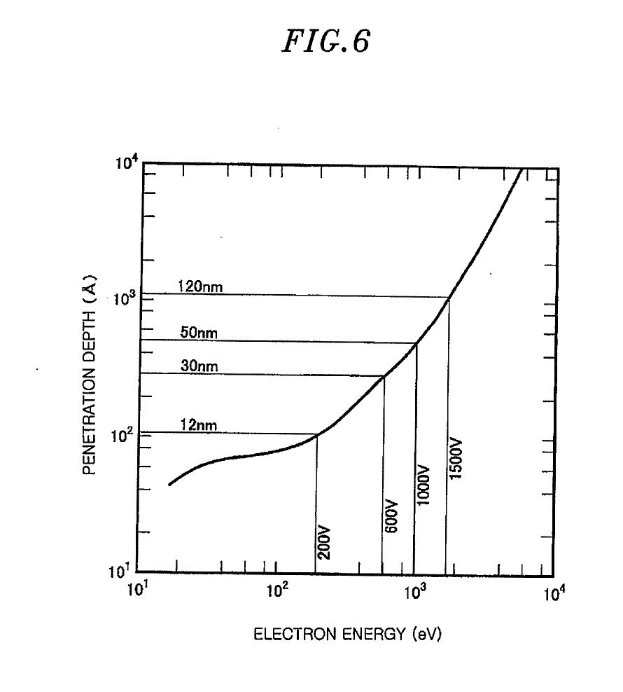

In general, it is theoretically known that, when electrons are injected into a resist, electron energy and electron penetration depth have substantially a proportional relationship, as shown in FIG. 6. According to this theory, the penetration depth is about 30 nm when the electron energy is 600 eV, about 50 nm when it is 1000 eV, and about 120 nm when it is 1500 eV.

However, if the absolute value of the negative DC voltage V_{DC} applied to the upper electrode 60 in the first pattern forming step S13 is too large, the anti-reflection film 114 may be excessively etched by plasma. Accordingly, it is preferable that the absolute value of the negative DC voltage V_{DC} applied to the upper electrode 60 is equal to or less than a predetermined absolute value V_{AB}. More specifically, the predetermined absolute value V_{AB} may be, for example, 600 V. Further, the absolute value of the negative DC voltage V_{DC} may be, for example, 600 V.

In the first pattern forming step S13, a temperature distribution in the plane of the wafer W supported by the susceptor 12 may be adjusted. Such adjustment allows for control of a distribution of the line width L2 of the second line portion 114a in the plane of the Wafer W, as will be described later.

Next, an irradiation step S14 is performed. In the irradiation step S14, the second line portion 114a made up of the resist film 115 and the anti-reflection film 114 is irradiated with electrons, as shown in FIG. 4D.

Like the first pattern forming step S13, in the irradiation step S14, an appropriate flow rate of process gas is introduced from the process gas supply unit 72 into the chamber 10 and the internal pressure of the chamber 10 is adjusted to a preset value by the exhauster 26. The first high frequency (equal to or more than 40 MHz) for plasma generation is applied from the high frequency power supply 74 to the upper electrode 60 via the matching device 76 and the upper power feed bar 78. Process gas discharged from the gas discharging holes 68 of the upper electrode 60 is made into plasma in the process space PS by the high frequency power applied between both electrodes 12 and 60.

However, the irradiation step S14 is performed for modification of the second line portion 114a formed in the first pattern forming step S13, not for etching. Accordingly, instead of CF-based gas such as CF₄, C₄F₈, CHF₃, CH₃F, CH₂F₂ and the like having high etching capability, for example, a mixture of hydrogen (H₂) gas and Ar gas and the like having low etching capability is used as the process gas.

Using the above-mentioned process gas, the line width L2 of the second line portion 114a made up of the resist film 115 and the anti-reflection film 114 is little changed in the irradiation step S14.

Like the first pattern forming step S13, in the irradiation step S14, a negative high DC voltage V_{DC} is applied from the variable DC power supply 80 to the upper electrode 60. When the DC voltage V_{DC} is applied to the upper electrode 60, ions (+) in the plasma PR are accelerated under an electric field of the upper ion sheath SH_{U} such that ion impact energy is increased in impact of the ions on the upper electrode 60 (the electrode plate 62) and secondary electrons (e⁻) emitted from the electrode plate 62 by discharging are increased. The secondary electrons (e⁻) emitted from the electrode plate 62 are injected into the surface of the wafer W on the susceptor 12 with a predetermined high energy. That is, the resist film 115 included in the second line portion 114a made up of the resist film 115 and the anti-reflection film 114 on the surface of the wafer W is irradiated with the electrons. Also in the irradiation step S14, the irradiation of the resist film 115 with the electrons allows high molecules of resist in the resist film 115 to absorb energy of the electrons, thereby causing change in its composition and structure, cross-linking reaction, etc. Accordingly, the second line portion 114a is modified.

In addition, in the irradiation step S14, since plasma etching is little performed by use of the process gas having low etching capability, the absolute value of the negative DC voltage V_{DC} applied to the upper electrode 60 may be set to be larger than the above-mentioned predetermined absolute value V_{AB}. More specifically, as described previously, when the predetermined absolute value V_{AB} is, for example, 600 V, the absolute value of the negative DC voltage V_{DC} may be, for example, 900 V.

Next, a silicon oxide film forming step S15 is performed. In the silicon oxide film forming step S15, the silicon oxide film 116 is formed to coat the second line portion 114a isotropically, as shown in FIG. 4E.

The silicon oxide film 116 is not limited to SiO₂ but may be made of SiOₓ different in composition ratio of oxygen and silicon from the SiO₂ film or a material having different composition containing silicon and oxygen as a main ingredient. Alternatively, the silicon oxide film 116 may be made of silicon oxy-nitride (SiON).

The formation of the silicon oxide film 116 is performed under a condition where the resist film 115 and the anti-reflection film 114 are left as the second line portion 114a. In general, it is preferable to form the silicon oxide film 116 at a low temperature (for example, 300° C. or below) since the resist film 115 is vulnerable to a high temperature. A method of forming the silicon oxide film 116 is sufficient if it can form the silicon oxide film 116 at a low temperature. In this embodiment, the formation of the silicon oxide film 116 may be performed by low temperature MLD (Molecular Layer Deposition). As a result, as shown in FIG. 4E, the silicon oxide film 116 is formed on the entire surface of the wafer W and is also formed on and coats the side of the second line portion 114a. At this time, when the thickness of the silicon oxide film 116 is set to D, the width of the silicon oxide film 116 coating the side of the second line portion 114a corresponds to D. The thickness D of the silicon oxide film 116 may be, for example, 30 nm.

Here, a process of forming the silicon oxide film using the low temperature MLD will be described.

The low temperature MLD alternates between a step of supplying silicon-containing raw material gas into a process chamber of a film forming apparatus and absorbing silicon raw material on the wafer W and a step of supplying oxygen-containing gas into the process chamber and oxidizing the silicon raw material.

More specifically, in the step of absorbing the silicon-containing raw material gas on the wafer W (hereinafter abbreviated as an “absorbing step”), aminosilane gas having two amino groups in one molecule (for example, bistertiarybutylaminisilane (BTBAS)), as the silicon-containing raw material gas, is supplied into the process chamber via supply nozzles of the silicon-containing raw material gas for a predetermined period of time. Accordingly, the BTBAS is absorbed on the wafer W.

Subsequently, in the step of supplying the oxygen-containing gas into the process chamber and oxidizing the BTBAS absorbed on the wafer W (hereinafter abbreviated as an “oxidizing step”), O₂ gas plasmalized by, for example, a plasma generation mechanism having a high frequency power supply, as the oxygen-containing gas, is supplied into the process chamber via gas supply nozzles for a predetermined period of time. Accordingly, the BTBAS absorbed on the wafer W is oxidized to form the silicon oxide film 116.

Additionally, a step of supplying purge gas into the process chamber while vacuum-exhausting the inside of the process chamber to remove residual gas remaining in the previous step (hereinafter abbreviated as a “purge step”) may be performed for a predetermined period of time between the absorbing step and the oxidizing step. Accordingly, the absorbing step, the purge step, the oxidizing step and the purge step are repeated in this order. An example of the purge gas may include inert gas such as, for example, nitrogen gas or the like. However, the purge step is sufficient if it can remove gas remaining in the process chamber. Accordingly, in the purge step, it is sufficient if the process chamber can be vacuum-exhausted without supplying the purge gas (also without supplying raw material gas).

Alternatively, raw material gas which contains organic silicon instead of the BTBAS may be used for the formation of the silicon oxide film 116 using the low temperature MLD. An example of the organic silicon-containing raw material gas may include an aminosilane-based precursor such as a monovalent or bivalent aminosilane precursor, including, for example, BTBAS (bistertiarybutylaminosilane), BDMAS (bisdimethylaminosilane), BDEAS (bisdiethylaminosilane), DPAS (diprophylaminosilane), BAS (butylaminosilane) and DIPAS (diisoprophylaminosilane).

A trivalent aminosilane precursor may be also used as the aminosilane-based precursor. An example of the trivalent aminosilane precursor may include TDMAS (tridimethylaminosilane).

In addition, instead of the aminosilane-based precursor, an ethoxysilane-based precursor may be used as the Si source gas which contains organic silicon. An example of the ethoxysilane-based precursor may include TEOS (tetraethoxysilane).

For the oxygen-containing gas, O₂, NO, N₂O, H₂O, O₃ gas and the like may be used and oxidizing agents produced by plasmalizing these gases under a high frequency electric field may be also used. The use of plasma of the oxygen-containing gas allows the silicon oxide film to be formed at equal to or less than 300° C. In addition, adjustment of flow rate of the oxygen-containing gas, power of a high frequency power supply and internal pressure of the process chamber allows the silicon oxide film to be formed at equal to or less than 100° or at the room temperature.

Next, an etch back step S16 is performed. In the etch back step S16, the silicon oxide film 116 is removed from the top of the second line portion 114a, while the silicon oxide film 116 is etched back to be left as a sidewall 116a of the second line portion 114a.

In the etch back step S16, in the plasma processing apparatus 100, an appropriate flow rate of process gas is again introduced from the process gas supply unit 72 into the chamber 10 and the internal pressure of the chamber 10 is adjusted to a preset value by the exhauster 26. The first high frequency (equal to or more than 40 MHz) for plasma generation is applied from the high frequency power supply 74 to the upper electrode 60 via the matching device and the upper power feed bar 78. Then, process gas discharged from the shower head 60 is dissociated/ionized by high frequency power discharge between both electrodes 12 and 60, thereby producing plasma.

In the etch back step S16, examples of the process gas may include mixtures of CF-based gas such as CF₄, C₄F₈, CHF₃, CH₃F, CH₂F₂ and the like, and Ar gas and so on, or gas obtained by adding oxygen to the mixtures as necessary.

Using the above-mentioned process gas, the silicon oxide film 116 is mainly anisotropically etched in a direction perpendicular to the wafer of the wafer W. As a result, the silicon oxide film 116 is removed from the top of the second line portion 114a, while it is only left as the sidewall 116a to cover the side of the second line portion 114a. At this time, a silicon oxide film 116 formed in a space defined between one second line portion 114a and another adjacent second line portion 114a is also removed. Hereinafter, a second line portion 114a whose side is covered by the sidewall 116a is referred to as a “side-covered line portion 114b.”

Assume that line width and space width of the side-covered line portion 114b are L2′ and S2′, respectively. Then, if the line width L2 of the second line portion 114a is 30 nm and thickness D of the sidewall 116 is 30 nm, L2′ can be 90 nm as L2′=L2+D×2 and S2′ can be 30 nm as S2′=S2−D×2.

Next, an etching step S17 of etching the mask film 113 is performed. In the etching step S17, the mask film 113 is etched using the side-covered line portion 114b including the sidewall 116a and the second line portion 114a, as a mask.

Also in the etching step S17, an appropriate flow rate of process gas is introduced from the process gas supply unit 72 into the chamber 10, the first high frequency (equal to or more than 40 MHz) power for plasma generation is applied to the upper electrode 60, and the second frequency (13.56 MHz) power for ion introduction is applied to the susceptor 12. The introduced process gas is plasmalized by high frequency discharging between both electrodes 12 and 60 and the mask film 113 is etched by radicals and ions produced by this plasma.

Also in the etching step S17, examples of the process gas may include mixtures of CF-based gas such as CF₄, C₄F₈, CHF₃, CH₃F, CH₂F₂ and the like, and Ar gas and so on, or gas obtained by adding oxygen to the mixtures as necessary.

In the etching step S17, the mask film 113 is etched in a region R1 corresponding to a space defined between a side-covered line portion 114b and another adjacent side-covered line portion 114b.

Next, a second pattern forming step S18 is performed. In the second pattern forming step S18, the second line portion 114a made up of the resist film 115 and the anti-reflection film 114 is ashed. Accordingly, a mask pattern including the third line portion 116a left as the sidewall 116a made up of the silicon oxide film 116 is formed. A section of the wafer W upon completing the second pattern forming step S18 is as shown in FIG. 4G.

Also in the second pattern forming step S18, an appropriate flow rate of process gas is introduced from the process gas supply unit 72 into the chamber 10, the first high frequency (equal to or more than 40 MHz) power for plasma generation is applied to the upper electrode 60, and the second frequency (13.56 MHz) power for ion introduction is applied to the susceptor 12. The introduced process gas is plasmalized by high frequency discharging between both electrodes 12 and 60 and the second line portion 114a made up of the resist film 115 and the anti-reflection film 114 is ashed by radicals and ions produced by this plasma.

In the second pattern forming step S18, examples of the process gas may include mixtures of hydrogen (H₂) gas, nitrogen (N₂) gas and the like.

Using the above-mentioned process gas, the second line portion 114a made up of the resist film 115 and the anti-reflection film 114 is ashed, and a pattern including the third line portion 116a left as the sidewall 116a made up of the silicon oxide film 116 is formed.

The third line portion 116a acts as a mask when the mask film 113 is etched. Assume that line width and space widths of the third line portion 116a are L3, and S3 and S3′, respectively. Then, if the line width L2 of the second line portion 114a is 30 nm and the thickness D of the sidewall 116 is 30 nm, L3 can be 30 nm as L3=D and S3 and S3′ can be 30 nm as S3=L2 and S3′=S2′.

That is, the third line portion 116a is arranged with the line width of L3, the space width of S3 and the interval of D2 (=L3+S3). Here, the interval D2=L3+S3=60 nm, which is half of the interval D1 (=L1+S1=120 nm) of the first line portion 115a. In addition, the line width L3 and the space width S3 of the third line portion 116a correspond to half of the line width L1 and the space width S1 of the first line portion 115a, respectively. That is, in this embodiment, a mask pattern including the third line portion 116a arranged with the second interval D2 (=60 nm) corresponding to half of the first line portion 115a arranged with the first interval D1 (=120 nm) is formed.

Next, a mask film etching step S19 is performed. In the mask film etching step S19, the mask film 113 is etched by the plasma with which the wafer W is irradiated, using the third line portion 116a as a mask. Accordingly, a fourth line portion 113a made up of the mask film 113 is formed as shown in FIG. 4H.

Also in the mask film etching step S19, an appropriate flow rate of process gas is introduced from the process gas supply unit 72 into the chamber 10, the first high frequency (equal to or more than 40 MHz) power for plasma generation is applied to the upper electrode 60, and the second frequency (13.56 MHz) power for ion introduction is applied to the susceptor 12. The introduced process gas is plasmalized by high frequency discharging between both electrodes 12 and 60 and the mask film 113 is etched by radicals and ions produced by this plasma.

Also in the mask film etching step S19, examples of the process gas may include mixtures of CF-based gas such as CF₄, C₄F₈, CHF₃, CH₃F, CH₂F₂ and the like, and Ar gas and so on, or gas obtained by adding oxygen to the mixtures as necessary.

Using the above-mentioned process gas, the mask film 113 is etched using the third line portion 116a made up of the silicon oxide film 116, as a mask. As a result, the fourth line portion 113a which is made up of the mask film 113 and has substantially the same line width as the third line portion 116a is formed.

Next, a film etching step S20 is performed. In the film to etching step S20, by etching a film to be etched 112 using the plasma with which the wafer W is irradiated, using the fourth line portion 113a made up of the mask film 113, as a mask, a fifth line portion 112a made up of the film to be etched 112 is formed as shown in FIG. 4I.

Also in the film etching step S20, an appropriate flow rate of process gas is introduced from the process gas supply unit 72 into the chamber 10, the first high frequency (equal to or more than 40 MHz) power for plasma generation is applied to the upper electrode 60, and the second frequency (13.56 MHz) power for ion introduction is applied to the susceptor 12. The introduced process gas is plasmalized by high frequency discharging between both electrodes 12 and 60 and the film to be etched 112 is etched by radicals and ions produced by this plasma.

Also in the film etching step S20, examples of the process gas may include mixtures of CF-based gas such as CF₄, C₄F₈, CHF₃, CH₃F, CH₂F₂ and the like, and Ar gas and so on, or gas obtained by adding oxygen to the mixtures as necessary.

Using the above-mentioned process gas, the film to be etched 112 is etched using the fourth line portion 113a made up of the mask film 113, as a mask. As a result, the fifth line portion 112a which is made up of the film to be etched 112 and has substantially the same line width as the third line portion 116a and the fourth line portion 113a is formed.

In addition, in the film etching step S20, a temperature distribution in the plane of the wafer supported by the susceptor 12 may be adjusted. Such adjustment allows for control of a distribution of the line width L3 of the fifth line portion 112a in the plane of the Wafer W, as will be described later.

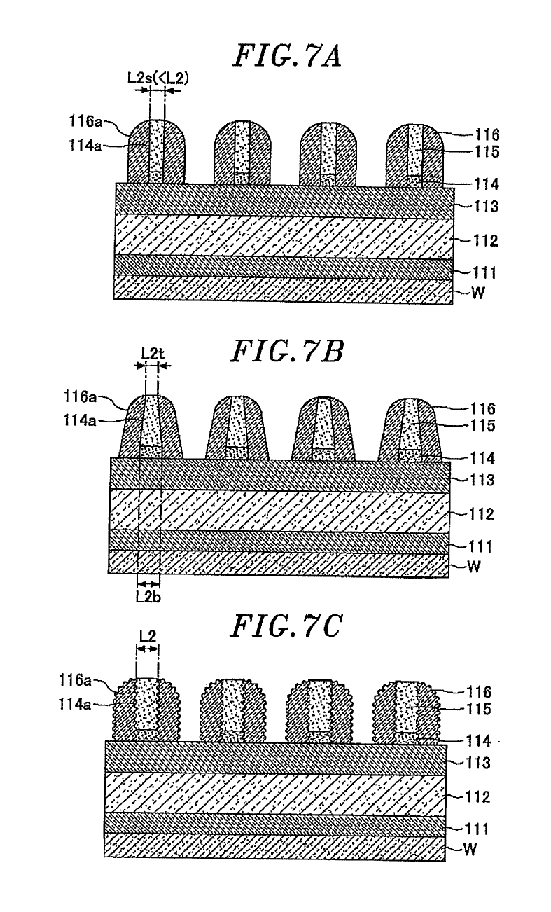

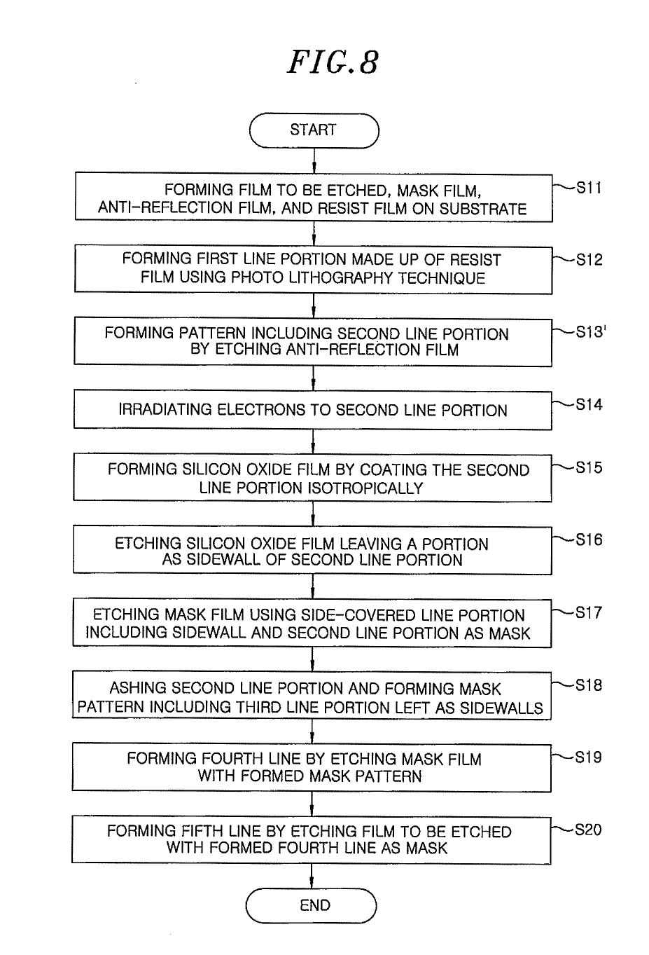

Next, in the method of forming a mask pattern and the method of manufacturing a semiconductor device in accordance to this embodiment, an effect of prevention of deformation of the core member made up of the resist film when the silicon oxide film is etched back will be described with reference to FIGS. 4B(f) and 7. FIGS. 7A to 7C are schematic sectional views showing a state of the wafer W after the etch back step S16 is performed in a conventional method of forming a mask pattern and a conventional method of manufacturing a semiconductor device.

Since the resist film 115 such as an ArF resist or the like is vulnerable to plasma or etching, a surface of the second line portion 114a made up of the resist film 115 tends to be roughened or a side of the second line portion 114a tends to be uneven when plasma etching is performed, which may result in deterioration of LER (Line Edge Roughness) or LWR (Line Width Roughness). In addition, since the second line portion 114a has a very small width, the second line portion 114 may appear to be meandered when viewed from top, by the unevenness of the side of the second line portion 114a, which may result in further deterioration of LER or LWR.

If the second line portion 114a made up of such a resist film 115 is used for the core member of SWP, the second line portion 114a is exposed to plasma when the silicon oxide film 116 is formed in the silicon oxide film forming step S15. Upon being exposed to plasma, the surface of the second line portion 114a may be roughened or deformed. In addition, when the silicon oxide film 116 is etched back in the etch back step S16, since the second line portion 114a is exposed to plasma as the silicon oxide film 116 on the second line portion 114a is removed, the surface of the second line portion 114a may be roughened or deformed.

For example, as shown in FIG. 7A, in the silicon oxide film forming step S15, when the line width of the second line portion 114a is decreased to L2s (<L2) by reaction with plasma, the third line portions 116a made up of the sidewalls 116a are alternately arranged with different space widths, which may result in difficulty in forming third line portions 116a having a desired shape.

In addition, for example, as shown in FIG. 7B, a line width on the top of the second line portion 114a may become smaller than a line width L2b of its root in the silicon oxide film step S15 and the etch back step S16. This is because the upper part of the second line portion 114a is more likely to be exposed to plasma than its lower part. In this case, the sidewalls 116a cannot be vertically formed on the surface of the wafer W and are alternately inclined in a reverse direction, which may result in difficulty in forming the third line portions 116a having a desired shape.

In addition, for example, as shown in FIG. 7C, the side of the second line portion 114a and the sidewall 116a may be roughened in the silicon oxide film step S15 and the etch back step S16. In this case, the above-mentioned LER or LWR of the third line portion 116a made up of the sidewall 116a may be deteriorated, which may result in difficulty in forming the third line portions 116a having a desired shape.

In addition, if the sidewall 116a is deformed, its deformed shape is transferred when the underlying mask layer 113 and film to be etched 112 are sequentially etched using the sidewall 116a as a mask. Accordingly, when the fifth line portion 112a is formed by etching the film to be etched 112, the fifth line portion 112a cannot be formed with high precision.

In accordance with this embodiment, the second line portion 114a made up of the resist film 115 is modified by irradiating the second line portion 114a with electrons before forming the silicon oxide film 116. As a result, since the second line portion 114a has improved plasma-resistance, the second line portion 114a as the core member can be prevented from being deformed when the silicon oxide film 116 is formed and then etched back to leave only the sidewall 116a. In addition, since the deformation of the second line portion 114a can be prevented, an underlying layer can be etched with high precision using the second line portion 114a as a mask. In addition, this can prevent a pattern formed by the etching from being collapsed.

It has been illustrated in this embodiment that the wafer W is irradiated with electrons to modify the second line portion 114a in either the first pattern forming step S13 or the irradiation step S14. However, the wafer W may be irradiated with electrons to modify the second line portion 114a until the silicon oxide film forming step S15 is performed. Accordingly, the second line portion 114a may be irradiated with electrons only in the irradiation step S14 without irradiating it with electrons in the first pattern forming step S13. FIG. 8 shows an example of electron irradiation only in the irradiation step S14. FIG. 8 is a flow diagram used to explain an example of the mask pattern forming method and the semiconductor device manufacturing method in accordance with this embodiment.

In FIG. 8, a first pattern forming step S13′ is replaced for the first pattern forming step S13 of FIG. 3. In the first pattern forming step S13′, a pattern including the second line portion 114a is formed by etching the anti-reflection film 114 without irradiation of electrons. Steps other than the first pattern forming step S13′ are the same as those in FIG. 3.

Examples 1 and 2 were carried out and a shape of the second line portion 114a whose side was covered by the sidewall 116a was evaluated by comparison of Examples 1 and 2 with Comparative Example 1. Results of the evaluation are listed in Table 1.

### Example 1

In Example 1, the steps S11 to S18 in FIG. 3 were performed. Conditions of the steps S13, S14 and S16 to S18 in Example 1 are as follows.

### (A) First Pattern Forming Step S13

Internal pressure of film forming apparatus: 800 mTorr

Power of high frequency power supply (40 MHz/13 MHz): 200/0 W

Voltage of upper electrode: −600 V

Wafer temperature (Center/perimeter): 30/30° C.

Flow rate of process gas (CF₄/O₂/Ar): 150/50/1000 sccm

Process time: 30 sec

### (B) Irradiation Step S14

Internal pressure of film forming apparatus: 100 mTorr

Power of high frequency power supply (40 MHz/13 MHz): 500/0 W

Voltage of upper electrode: −900 V

Wafer temperature (Center/perimeter): 30/30° C.

Flow rate of process gas (H₂/Ar): 450/450 sccm

Process time: 10 sec

### (C) Etch Back Step S16

Internal pressure of film forming apparatus: 30 mTorr

Power of high frequency power supply (40 MHz/13 MHz): 500/100 W

Voltage of upper electrode: 300 V

Wafer temperature (Center/perimeter): 30/30° C.

Flow rate of process gas (C₄F₆/Ar/O₂): 15/450/22.5 sccm

Process time: 25 sec

### (D) Etching Step S17

Internal pressure of film forming apparatus: 30 mTorr

Power of high frequency power supply (40 MHz/13 MHz): 400/0 W

Voltage of upper electrode: 0 V

Wafer temperature (Center/perimeter): 30/30° C.

Flow rate of process gas (CF₄/CHF₃/O₂): 125/125/20 sccm

Process time: 12 sec

### (E) Second Pattern Forming Step S18

Internal pressure of film forming apparatus: 100 mTorr

Power of high frequency power supply (40 MHz/13 MHz): 500/0 W

Voltage of upper electrode: 0 V

Wafer temperature (Center/perimeter): 30/30° C.

Flow rate of process gas (H₂/N₂): 300/900 sccm

Process time: 60 sec

### Example 2

In Example 2, the steps S11 to S18 in FIG. 8 were performed. Conditions of the steps S14 and S16 to S18 in Example 2 are the same as Example 1. Conditions of the step S13′ in Example 2 are as follows.

### (F) First Pattern Forming Step S13′

Internal pressure of film forming apparatus: 800 mTorr

Power of high frequency power supply (40 MHz/13 MHz): 200/0 W

Voltage of upper electrode: 0 V

Wafer temperature (Center/perimeter): 30/30° C.

Flow rate of process gas (CF₄/O₂/Ar): 150/20/1000 sccm

Process time: 55 sec

### Comparative Example 1

In Comparative Example 1, the step S14 in FIG. 8 was omitted and the steps S11, S12, S13′ and S15 to S18 were performed. Conditions of the steps S16 to S18 in Comparative Example 1 are the same as Example 1. Conditions of the step S13′ in Comparative Example 1 are the same as Example 2.

Table 1 shows the line width L2 of the second line portion 114a whose side is covered by the sidewall 116a after the etch back step S16 is performed in Examples 1 and 2 and Comparative Example 1.

TABLE 1

| | | | Comparative |
|---|---|---|---|
| Ex | Ex 1 | Ex 2 | Ex 1 |
| Electron irradiation | ◯ | X | X |
| in first pattern | | | |
| forming step (S13) | | | |
| Electron irradiation | ◯ | ◯ | X |
| in irradiation step | | | |
| (S14) | | | |
| Line width of second | 33.3 | 28.3 | 25.6 |
| line portion [nm] | | | |

As shown in Table 1, the line width L2 of the second line portion 114a in Comparative Example 1 is 25.6 nm, while the line width L2 of the second line portion 114a in Example 2 is 28.3 nm, i.e., the line width L2 in Example 2 is larger than that in Comparative Example 1. Accordingly, the second line portion 114a can be prevented from being deformed in the silicon oxide film forming step S15 and the etch back step S16 by electron irradiation in the irradiation step S14.

In addition, as shown in Table 1, the line width L2 of the second line portion 114a in Comparative Example 1 is 25.6 nm and the line width L2 of the second line portion 114a in Example 2 is 28.3 nm, while the line width L2 of the second line portion 114a in Example 1 is 33.3 nm, i.e., the line width L2 in Example 1 is larger than those in Comparative Example 1 and Example 2. Accordingly, the second line portion 114a can be further prevented from being deformed in the silicon oxide film forming step S15 and the etch back step S16 by both of electron irradiation in the irradiation step S14 and electron irradiation in the first pattern forming step S13.

Next, an effect of making a distribution of the line width L2 of the second line portion 114a in the plane of the wafer W uniform by adjusting a temperature distribution in the plane of the wafer W supported by the susceptor 12 in the first pattern forming step S13 will be described with reference to Table 2.

For the conditions (A), the temperature distribution of the wafer W was adjusted by changing temperature TO of the perimeter of the wafer W with temperature TI of the center of the wafer W constant (at 30° C.) and a variation of the line width CD in the plane of the wafer W was obtained. Other conditions are the same as the conditions (A).

Table 2 shows CD shift amount in the most peripheral portion of the wafer W when the perimeter temperature TO of the wafer W is 20° C., 30° C. and 40° C., based on the perimeter temperature TO of 30° C.

The size of the wafer W was 300 mmΦ. The shift amount means a difference between the line width L1 of the first line portion 115a before trimming (the first pattern forming step S13) and the line width L2 of the second line portion 114a after trimming (the first pattern forming step S13).

TABLE 2

| | | | |
|---|---|---|---|
| Center | 30 | 30 | 30 |
| temperature | | | |
| TI (° C.) of | | | |
| wafer | | | |
| Perimeter | 20 | 30 | 40 |
| temperature | | | |
| TO (° C.) of | | | |
| wafer | | | |
| CD shift | −3 | 0 | 2 |
| amount based | | | |
| on TO = 30° C. | | | |

As shown in Table 2, when the perimeter temperature TO is 20° C. which is lower by 10° C. than the center temperature TI, the CD shift amount in the most peripheral portion of the wafer W is smaller by 3 nm than that when the perimeter temperature TO is 30° C. In addition, when the perimeter temperature TO is 40° C. which is higher by 10° C. than the center temperature TI, the CD shift amount in the most peripheral portion of the wafer W is larger by 2 nm than that when the perimeter temperature TO is 30° C. Accordingly, the line width L2 of the second line width 114a after trimming (the first pattern forming step S13) can be independently controlled in the center and perimeter of the wafer W by adjusting the center temperature TI and the perimeter temperature TO independently.

Accordingly, in the first pattern forming step S13, by adjusting the temperature distribution in the plane of the wafer W supported by the susceptor 12, the distribution of the line width L2 of the second line portion 114a in the plane of the wafer W can be uniformalized.

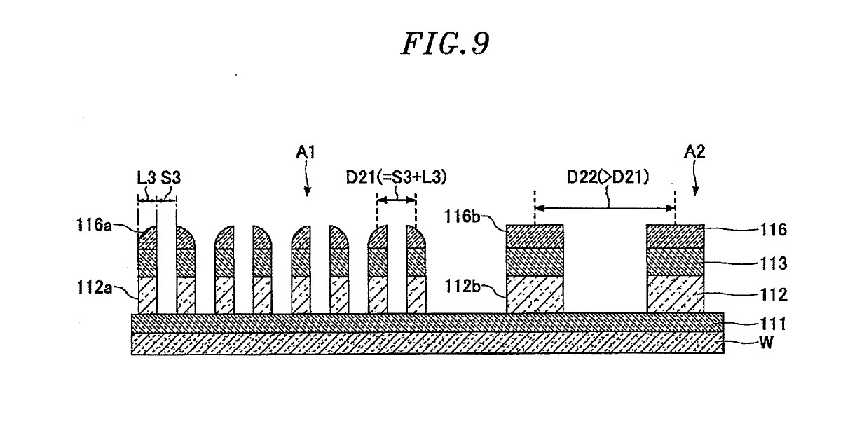

Next, an effect of making a distribution of the line width L3 of a fifth line portion 112a made up of the film to be etched 112 in the plane of the wafer W uniform in either a dense portion A1 or a sparse portion A2 by adjusting a temperature distribution in the plane of the wafer W in the etch-targeted etching step S20 will be described with reference to FIG. 9 and Table 3. FIG. 9 is a schematic sectional view showing a state of the wafer W provided with a dense portion A1 and a sparse portion A2.

While the second pattern forming step S18 is performed to provide a region A1 where the third line portions 116a are arranged at smaller intervals D21 (S3+L3) (hereinafter referred to as a “dense portion”), a region A2 where the third line portions 116b are arranged at larger intervals D22, which are larger than the intervals D21, (hereinafter referred to as a “sparse portion”) is provided. In order to form the third line portion 116b, after forming the silicon oxide film 116, the region A1 is protected by a separate resist film or the like, and a pattern including the third line portion 116b made up of another resist film is formed in the region A2. Then, the fifth line portions 112a and 112b are formed by performing the mask film etching step S19 and the film etching step S20 using the mask pattern including the formed third line portions 116a and 116b. The region A1 where the fifth line portions 112a is arranged at smaller intervals D21 (S3+L3) is provided in the left side of FIG. 1, and the region A2 where the fifth line portion 112b are arranged at larger intervals D22, which are larger than the intervals D21, is provided in the right side of FIG. 9.

In addition, the dense portion A1 and the sparse portion A2 were separately provided by performing the steps S11 through S18 in FIG. 3 under the conditions (A) to (E) in Example 1. Thereafter, the step S19 was performed under the same conditions as the step S17 shown in the conditions (D) and the step S20 was performed under the following conditions (G). In this case, the temperature distribution in the plane of the wafer W was adjusted by changing the perimeter temperature TO of the wafer W with the center temperature TI constant (at 50° C.). Then, line widths of the fifth line portions 112a and 112b in the dense portion A1 and the sparse portion A2 were obtained. Other conditions are the same as the following conditions (G). In addition, a polysilicon film was used for the film 112.

### (G) Film to be Etched Etching Step S20

Internal pressure of film forming apparatus: 25 mTorr

Power of high frequency power supply (40 MHz/13 MHz): 1500/1500 W

Voltage of upper electrode: 300 V

Wafer temperature (Center): 50° C.

Flow rate of process gas (C₄F₈/Ar/O₂): 50/700/37 sccm

Process time: 40 sec

Table 3 shows line widths of the fifth line portions 112a and 112b of the dense portion A1 and the sparse portion A2 in the center and perimeter of the wafer W when the perimeter temperature TO of the wafer is 40° C., 50° C. and 60° C. In Table 3, LI31 and LO31 denote line widths of the fifth line portion 112a of the dense portion A1 in the center and perimeter of the wafer W, respectively. In addition, LI32 and LO32 denote line widths of the fifth line portion 112b of the sparse portion A2 in the center and perimeter of the wafer W, respectively.

TABLE 3

| | | | |
|---|---|---|---|
| Center temperature TI (° C.) of | 50 | 50 | 50 |
| wafer | | | |
| Perimeter temperature TO (° C.) | 40 | 50 | 60 |
| of wafer | | | |
| Line width LI31 (nm) of | 27.8 | 28.0 | 27.6 |
| fifth line portion of dense | | | |
| portion A1 in center of | | | |
| wafer | | | |
| Line width LO31 (nm) of | 28.8 | 27.8 | 27.0 |
| fifth line portion of dense | | | |
| portion A1 in perimeter of | | | |
| wafer | | | |
| LI31 − LO31 (nm) | −1.0 | 0.2 | 0.6 |
| Line width LI32 (nm) of | 269 | 271 | 269 |
| fifth line portion of sparse | | | |
| portion A2 in center of | | | |
| wafer | | | |
| Line width LO32 (nm) of | 280 | 267 | 262 |
| fifth line portion of sparse | | | |
| portion A2 in perimeter of | | | |
| wafer | | | |
| LI32 − LO32 (nm) | −11 | 4 | 7 |

As shown in Table 3, when the perimeter temperature TO is adjusted between 40° C. and 60° C., a difference (LI31-LO31) between the line widths of the fifth line portion 112a of the dense portion A1 in the center and perimeter of the wafer W can be freely changed from −1.0 nm to 0.6 nm. Accordingly, since the difference (LI31-LO31) may be 0, the distribution of the line widths of the fifth line portion 112a of the dense portion A1 in the center and perimeter of the wafer W can be uniformalized.

In addition, when the perimeter temperature TO is adjusted between 40° C. and 60° C., a difference (LI32-LO32) between the line widths of the fifth line portion 112b of the sparse portion A2 in the center and perimeter of the wafer W can be freely changed from −11 nm to 7 nm. Accordingly, since it is possible to set the difference (LI32-LO32) to 0, the distribution of the line widths of the fifth line portion 112a of the sparse portion A2 in the center and perimeter of the wafer W can be also uniformalized.

As shown in Table 3, when the perimeter temperature TO of the wafer W is changed, the difference in line width of the dense portion A2 between the center and perimeter of the wafer W is more varied than the difference in line width of the dense portion A1 between the center and perimeter of the wafer W. It is believed that this is because the fifth line portion 112b in the sparse portion A2 is more likely to contact and react with plasma than the fifth line portion 112a in the dense portion A1. A speed of reaction of the fifth line portions 112a and 112b with plasma and a sticking coefficient with which reaction products are again stuck to the fifth line portions 112a and 112b depend on temperature. Accordingly, when the temperature of the wafer W is changed, the line width of the fifth line portion 112b in the sparse portion A2 is more varied than the line width of the fifth line portion 112a in the dense portion A1.

Accordingly, the line width in the sparse portion A2 can be more varied than the line width in the dense portion A1 by adjusting the temperature distribution of the wafer W. In addition, as shown in Table 3, it is possible to make the line width LI32 in the sparse portion A2 of the center of the wafer W and the line width LO32 in the sparse portion A2 of the perimeter of the wafer W approximately equal to each other while making the line width LI31 in the dense portion A1 of the center of the wafer W and the line width LO31 in the dense portion A1 of the perimeter of the wafer W approximately equal to each other.

As described above, in accordance with this embodiment, when a fine mask pattern is formed using the SWP method, the second line portion 114a is modified by irradiating the second line portion 114a as the core member of the sidewall 116a with electrons before forming the silicon oxide film 116 as the sidewall 116a. Accordingly, when the silicon oxide film 116 is formed and etched back, it is possible to prevent the second line portion 114a as the core member made up of the resist film 115 from being deformed.

In addition, in accordance with this embodiment, the temperature distribution in the plane of the wafer W is adjusted in either the first pattern forming step S13 or the film etching step S20. Accordingly, it is possible to uniformalize the distribution of line widths of the second line portion 114a and the fifth line portion 112a in the center and perimeter of the wafer W.

It has been illustrated in this embodiment that the anti-reflection film 114 is etched while the first line portion 115a is trimmed in the first pattern forming step S13. However, this embodiment may be applied to a case where the first line portion 115a is not trimmed in the first pattern forming step S13, i.e., the line width L2 of the second line portion 114a is approximately equal to the line width L1 of the first line portion 115a. This shows the same effects as the case where the first line portion 115a is trimmed.

In addition, it has been illustrated in this embodiment that electron irradiation is performed in both of the first pattern forming step S13 and the irradiation step S14 or only in the irradiation step S14. However, the electron irradiation may be performed before the silicon oxide film forming step S15 is performed. Accordingly, the electron irradiation may be performed before the first pattern forming step S13 after the photolithography step S12.

### Second Embodiment

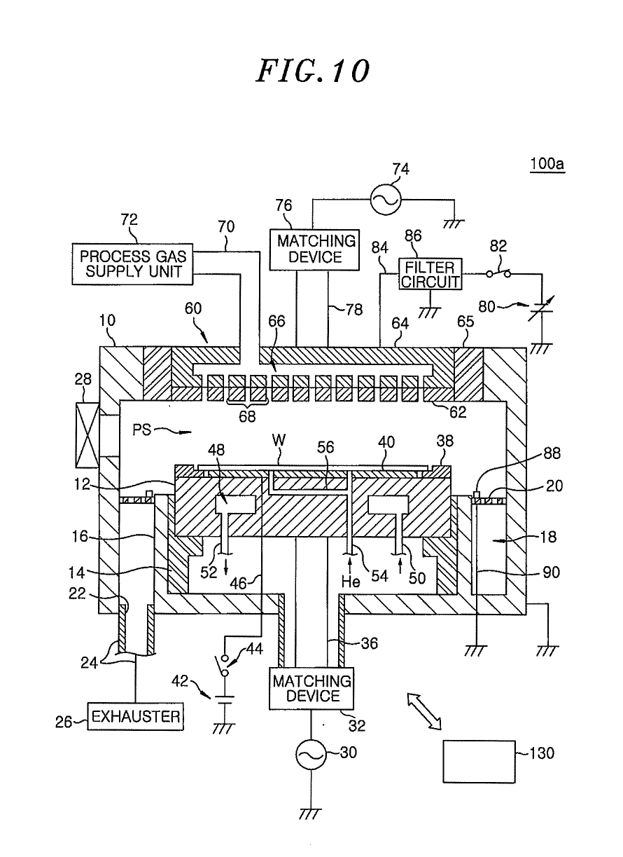

Next, a method of forming a mask pattern in accordance with a second embodiment of the present invention will be described with reference to FIG. 10.

This embodiment is different from the first embodiment in that the temperature distribution in the plane of the wafer W is adjusted in neither the first pattern forming step S13 nor the film to be etched etching step S20.

FIG. 10 is a schematic sectional view showing a plasma processing apparatus 100a suitable to perform the method of forming the mask pattern in accordance with this embodiment. In FIG. 10, the same elements as FIG. 1 are denoted by the same reference numerals and explanation of which is not repeated.

As shown in FIG. 10, the plasma processing apparatus 100a in accordance with this embodiment has the same configuration as the plasma processing apparatus 100 of FIG. 1 in accordance with the first embodiment except that no temperature distribution adjusting unit is provided in the susceptor 12.

In this embodiment, an annular refrigerant passage 48 extending in a circumferential direction is provided in the susceptor 12 without providing any temperature distribution adjusting unit. A refrigerant (e.g., cooling water) is circulated into the refrigerant passage 48 from a chiller unit (not shown) via pipes 50 and 52. The temperature of the wafer W on the electrostatic chuck 40 can be controlled based on the temperature of the refrigerant.

In addition, like the first embodiment, in order to further improve the accuracy of the temperature of the wafer W, heat transfer gas (e.g., He gas) from a heat transfer gas supply unit (not shown) is supplied between the electrostatic chuck 40 and the wafer W via the gas supply pipe 54 and the gas passage 56 in the susceptor 12.

The mask pattern forming method and a semiconductor device manufacturing method in accordance with this embodiment may be the same as those shown in FIGS. 3 and 8 in accordance with the first embodiment. However, since this embodiment employs the plasma processing apparatus 100a having no temperature distribution adjusting unit, the temperature distribution in the plane of the wafer W is adjusted in neither the first pattern forming step S13 nor the film etching step S20.

Even with this embodiment, when a fine mask pattern is formed using the SWP method, the second line portion 114a is modified by irradiating the second line portion 114a as the core member of the sidewall 116a with electrons before forming the silicon oxide film 116 as the sidewall 116a. Accordingly, when the silicon oxide film 116 is formed and etched back, it is possible to prevent the second line portion 114a as the core member made up of the resist film 115 from being deformed.

In addition, this embodiment may be also applied to a case where the first line portion 115a is not trimmed in the first pattern forming step S13. This also shows the same effects as the case where the first line portion 115a is trimmed. In addition, even with this embodiment, the electron irradiation may be performed before the first pattern forming step S13 after the photolithography step S12.

While the invention has been shown and described with respect to the embodiments, it will be understood by those skilled in the art that various changes and modifications may be made without departing from the scope of the invention as defined in the following claims.

This application claims priority based on Japanese Patent Application NO. 2010-085956, filed on Apr. 2, 2010.

What is claimed is:

1. A method of forming a mask pattern, comprising:
a first pattern forming step of etching an anti-reflection coating film by using as a mask a first line portion made up of a photo resist film formed on the anti-reflection film to form a pattern including a second line portion made up of the photo resist film and the anti-reflection film;
an irradiation step of irradiating the photo resist film with electrons;
a silicon oxide film forming step of forming a silicon oxide film to cover the second line portion isotropically;
an etch back step of etching back the silicon oxide film such that the silicon oxide film is removed from the top of the second line portion as sidewalls of the second line portion; and
a second pattern forming step of ashing the second line portion to form a mask pattern including a third line portion which is made up of the silicon oxide film and remains as the sidewalls.

2. The method of claim 1, wherein the irradiation step includes irradiating the photo resist film included in the second line portion with electrons.

3. The method of claim 1, wherein the first pattern forming step includes etching the anti-reflection film while irradiating the first line portion with electrons.

4. The method of claim 1, wherein the first pattern forming step includes trimming the first line portion and forming a pattern including the second line portion which is made up of the photo resist film and the anti-reflection film has a line width smaller than that of the first line.

5. The method of claim 1, wherein in the first pattern forming step, adjusting an in-plane distribution of line width of the second line portion of a substrate is controlled by an in-plane temperature distribution of the substrate.

6. A method of manufacturing a semiconductor device, comprising:
a stacking step of stacking a film to be etched, a mask film, an anti-reflection film and a photo resist film on a substrate;
a photolithography step of forming a first line portion from the photo resist film by using a photolithography technique;
a mask pattern forming step of forming a mask pattern by using the mask pattern forming method described in claim 1;
a mask film etching step of etching the mask film by using the formed mask pattern to form a fourth line portion made up of the mask film; and
a film etching step of etching the film to be etched by using the formed fourth line portion as a mask to form a fifth line portion made up of the film to be etched.

7. The method of claim 6, wherein in the film etching step, adjusting an in-plane distribution of line width of the fifth line portion of a substrate is controlled by an in-plane temperature distribution of the substrate.
